(19) United States
(12) Patent Application Publication
(10) Pub. No.: US 2018/0277434 A1
(43) Pub. Date: Sep. 27, 2018

(54) PROCESS OF FORMING OHMIC ELECTRODE ON NITRIDE SEMICONDUCTOR MATERIAL

(71) Applicants: Sumitomo Electric Industries, Ltd., Osaka-shi (JP); SUMITOMO ELECTRIC DEVICE INNOVATIONS, INC., Yokohama-shi (JP)

(72) Inventors: Hiroyuki Ichikawa, Yokohama-shi (JP); Masahiro Nishi, Yokohama-shi (JP)

(73) Assignees: Sumitomo Electric Industries, Ltd., Osaka-shi (JP); SUMITOMO ELECTRIC DEVICE INNOVATIONS, INC., Yokohama-shi (JP)

(21) Appl. No.: 15/928,901

(22) Filed: Mar. 22, 2018

(30) Foreign Application Priority Data
Mar. 24, 2017 (JP) 2017-059095

(51) Int. Cl. H01L 21/768; H01L 21/285; H01L 23/532

(52) U.S. Cl. CPC H01L 21/76886; H01L 23/53261; H01L 23/53219; H01L 21/28575

(57) ABSTRACT

A process of forming an ohmic electrode containing aluminum (Al) on a nitride semiconductor material is disclosed. The process includes steps of: (a) depositing an ohmic metal on the semiconductor material; (b) forming an insulating film such that the insulating film covers a side of the ohmic metal but exposes a top of the ohmic metal; and (c) alloying the ohmic metal at a temperature higher than 500° C. for 30 to 60 seconds.

### CROSS REFERENCE TO RELATED APPLICATION

The present application is based on and claims the benefit of priority of Japanese Patent Application No. 2017-059095, filed on Mar. 24, 2017, the entire content of which is incorporated herein by reference.

### BACKGROUND OF INVENTION

### 1. Field of Invention

The present invention relates to a process of forming an ohmic electrode on a nitride semiconductor material.

### 2. Background Arts

An ohmic electrode on a nitride semiconductor material is generally formed by alloying an ohmic metal. Japanese Patent Applications laid open No. JP-2010-171133A and JP-2006-351762A have disclosed processes of forming a semiconductor device made of primarily nitride semiconductor materials. When an ohmic metal is alloyed covered with no insulating film, the surface of the semiconductor material is degraded due to, for instance, dissociation of nitrogen atom therefrom. When the ohmic metal is alloyed fully covered with an insulating film, the contact resistance between the ohmic electrode and the semiconductor material increases.

### SUMMARY OF INVENTION

An aspect of the present invention relates to a process of forming an ohmic electrode on a nitride semiconductor material. The process includes steps of (a) depositing an ohmic metal on the nitride semiconductor material, (b) forming an insulating film so as to cover a side of the ohmic metal bur expose a top thereof, and (c) alloying the ohmic metal. The alloying is carried out at a temperature higher than 500° C. for a period of 30 to 60 seconds. The insulating film, which may be formed by a plasma-enhanced chemical vapor deposition (p-CVD) technique, has refractive index smaller than 1.9 and a thickness greater than 10 nm.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1A to FIG. 1D show cross sections of a semiconductor device at respective steps of a process according to the first embodiment of the present invention;

FIG. 2A to FIG. 2C show cross sections of the semiconductor device at respective steps subsequent to that shown in FIG. 1D;

FIG. 3A to FIG. 3D show cross sections of a semiconductor device at respective steps of a process according to the second embodiment of the present invention;

FIG. 4A to FIG. 4D show cross sections of the semiconductor device at respective steps subsequent to that shown in FIG. 3D;

FIG. 5A to FIG. 5C show cross sections of the semiconductor device at respective steps subsequent to that shown in FIG. 4D; and

FIG. 6A shows a SEM photograph of the semiconductor device formed by a conventional process and FIG. 6B show a SEM photograph of the semiconductor device formed by the process according to the present invention.

### DESCRIPTION OF EMBODIMENTS

Next, some embodiments according to the present invention will be described as referring to drawings. The present invention is not restricted to those embodiments, and may have a scope defined by claims attached, and various changes and modifications with a scope equivalent to the claims.

### First Embodiment

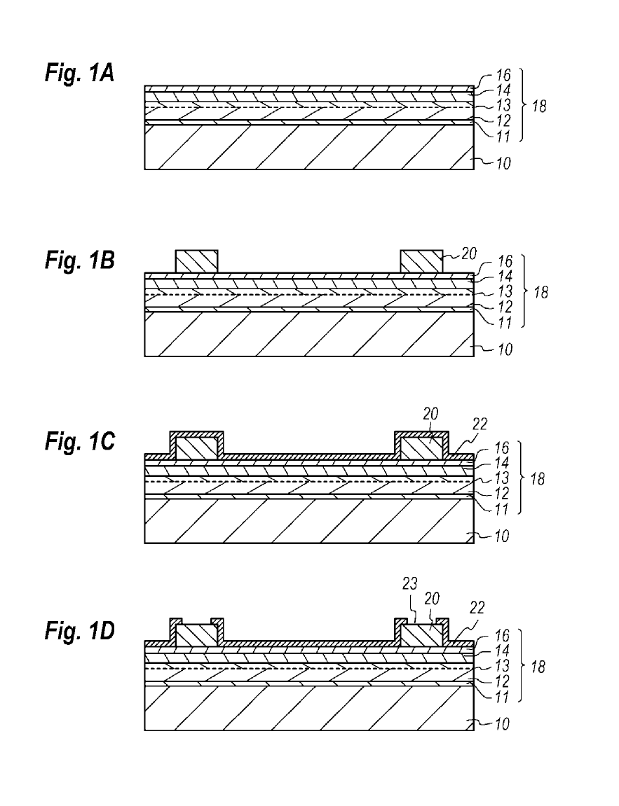

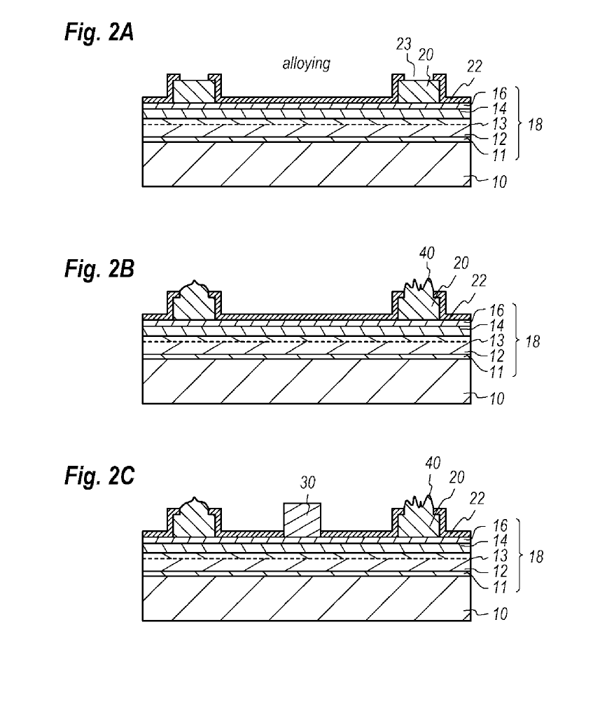

Cross sections of a semiconductor device at respective steps of a process according to the first embodiment of the present invention are shown in FIG. 1A to FIG. 2C. The process first grows a semiconductor stack 18 on a substrate 10 by a metal organic chemical vapor deposition (MOCVD) technique, where the substrate 10 may be made of silicon carbide (SiC), sapphire (Al₂O₃), and/or silicon (Si). The semiconductor stack 18 includes a buffer layer 11, a channel layer 12, a barrier layer 14, and a cap layer 16.

Thereafter, an ohmic metal 20 is formed on the semiconductor stack 18 by sequential processes of patterning photoresist, evaporating metals, and removing the patterned photoresist accompanying with residual metals deposited thereon. The ohmic metal 20 includes, from a side of the semiconductor stack 18, a titanium (Ti) film with a thickness of 20 nm, an aluminum (Al) film with a thickness of 100 nm, another Ti film or a nickel (Ni) film with a thickness of 20 nm, and a gold (Au) film with a thickness of 50 nm, namely Ti/Al/Ti/Au. In an alternative, the ohmic metal 20 may include a tantalum (Ta) film with a thickness of 10 nm, an Al film with a thickness of 300 nm, another Ta film with a thickness of 10 nm, and an Au film, namely, Ta/Al/Ta/Au. The Ti film or the Ta film closest to the semiconductor stack 18 may deoxidize an oxidized layer in topmost of the semiconductor stack 18 and combine with nitrogen (N) in the semiconductor stack 18 to from vacancies therein. The vacancies thus formed may induce tunnel effect between the semiconductor stack 18 and the ohmic metal 20 to reduce the contact resistance therebetween. The Al film next to the Ti or Ta film may be electrically in contact with the semiconductor stack 18. That is, the tunnel effect may occur between the Al film and the semiconductor stack 18. The other Ti film or the Ni film may operate as a barrier film that prevents inter-diffusion between the Au film and the Al film. The Au film in the topmost may prevent the oxidization of the Ti film or the Ni film, and the Al film. The Au film may also decrease the contact resistance against an interconnection to be in contact thereto.

Thereafter, the process forms an insulating film 22 such that the insulating film 22 covers a top of the semiconductor stack 18 and the ohmic metal 20. The insulating film 22 is preferably made of silicon nitride (SiN) with refractive index smaller than 1.9. The insulating film 22, which may be formed by the metal organic chemical vapor deposition (MOCVD) technique, has a thickness of, for instance, 40 nm.

Thereafter, the insulating film 22 in a portion at a top of the ohmic metal 20 is removed to leave an opening 23 there by etching the insulating film 22 using a reactive gas containing fluorine (F) for the dry-etching, or a hydrofluoric acid for the wet-etching. The insulating film 22 is necessary at least to cover a side of the ohmic metal 20 and have a portion to expose the ohmic metal 20. Accordingly, the insulating film 22 in the ends thereof is unnecessary to ride on the top of the ohmic metal 20. In order to securely cover the side of the ohmic metal 20, the insulating film 22 preferably rides on the top of the ohmic metal 20 by, for instance, about 5 μm.

Then, the process carries out heat-treatment, or alloys the ohmic metal 20 as shown in FIG. 2A at a temperature 500 to 900° C., specifically, at 850° C. in the present embodiment. When the ohmic metal 20 includes a titanium Ti film in the bottom thereof, that is, a metal film in contact with the nitride semiconductor material is titanium (Ti), the temperature for alloying the ohmic metal 20 is preferably 700 to 900° C. and a period from 30 to 60 seconds. While, a metal film in contact with the nitride semiconductor material is tantalum (Ta), the temperature is preferably 500 to 700° C. The present embodiment, where the ohmic metal 20 is stacked metals of Ti/Al/Ti/Au, alloys the ohmic metal 20 at 850° C. for 60 seconds.

The alloying, or the heat-treatment, leaves a lot of lumps on the top of an ohmic electrode 20 but no lumps nor no bumps appear in the side of the ohmic electrode 20, as shown in FIG. 2B.

Thereafter, another opening is formed in the insulating film 22 between two ohmic electrodes 20, as shown in FIG. 2C. Then, the gate electrode 30 that comprises stacked metals of nickel (Ni) and gold (Au) is formed within the opening, where Ni is in contact with the semiconductor stack 18 as a Schottky metal.

The first embodiment thus described covers the side of the ohmic metal 20 with the insulating film 22 but this insulating film 22 exposes the top of the ohmic metal 20; then, the ohmic metal 20 is alloyed. Accordingly, the process of the embodiment may prevent the lumps appearing in edges 44 of the ohmic electrode 20. The lumps protruding from the edge of the ohmic electrode 20 disarranges the electric field extending between the electrodes, 20 and 30. Also, because the insulating film 22 exposes the top of the ohmic metal 20, which may suppress inter-diffusion between elements in the insulating film 22 and those in the ohmic metal 20, the contact resistance between the ohmic electrode 20 and the semiconductor stack 18 may be kept in a value where the ohmic metal 20 is alloyed without any insulating film 22.

Considering an aspect ratio in a cross section of the ohmic metal 20, that is, a total thickness of the ohmic metal 20 is merely a few hundreds of nanometers; while, a width thereof is generally greater than a few scores of micron-meters. Accordingly, an arrangement where the top of the ohmic metal 20 is exposed means that the ohmic metal 20 is bare, or almost isolated within an ambient. Accordingly, the alloying the ohmic metal 20 as exposing the top thereof may cause substantially no influence in the contact resistance. On the other hand, when the ohmic metal 20 is fully covered with the insulating film 22, the alloying the ohmic metal 20 also accelerates the inter-diffusion between the elements in the insulating film 22 and those in the ohmic metal 20. In particular, when the insulating film 22 contains silicon (Si) and the ohmic metal 20 contains aluminum (Al), the alloying concurrently forms aluminum silicide (AlSi) which increases resistance thereof and also the contact resistance against the nitride semiconductor material.

When the alloying is carried out at a temperature higher than 500° C. like the present embodiment, the semiconductor stack 18 made of nitride semiconductor materials degrades quality thereof due to, primarily, dissociation of nitrogen (N) from the surface thereof. The present embodiment covers the surface of the semiconductor stack 18 by the insulating film 22. That is, the insulating film 22 covers not only the side of the ohmic metal 20 but the surface of the semiconductor stack 18 during the heat treatment for alloying. Accordingly, the semiconductor stack 18 may be effectively protected from the dissociation of nitrogen (N).

Besides, the insulating film 22 of the present embodiment is made of SiN with refractive index smaller than 1.9, which means that the SiN film 22 in the composition thereof is closer to the stoichiometric composition, namely, Si₃N₄; while, an SiN film with Si-rich composition shows higher refractive index. An SiN film with the stoichiometric composition has less Si dangling bonds to be bound with aluminum (Al) in the ohmic metal 20. As described above, when Al elements are bound with Si elements to form aluminum silicide (AlSi), such a silicide compound increases resistivity thereof and concurrently the contact resistance against the nitride semiconductor material. The present embodiment, accompanied with the arrangement where the insulating film 22 exposes the top of the ohmic metal 20, may keep the contact resistance against the semiconductor stack 18 low enough.

### Second Embodiment

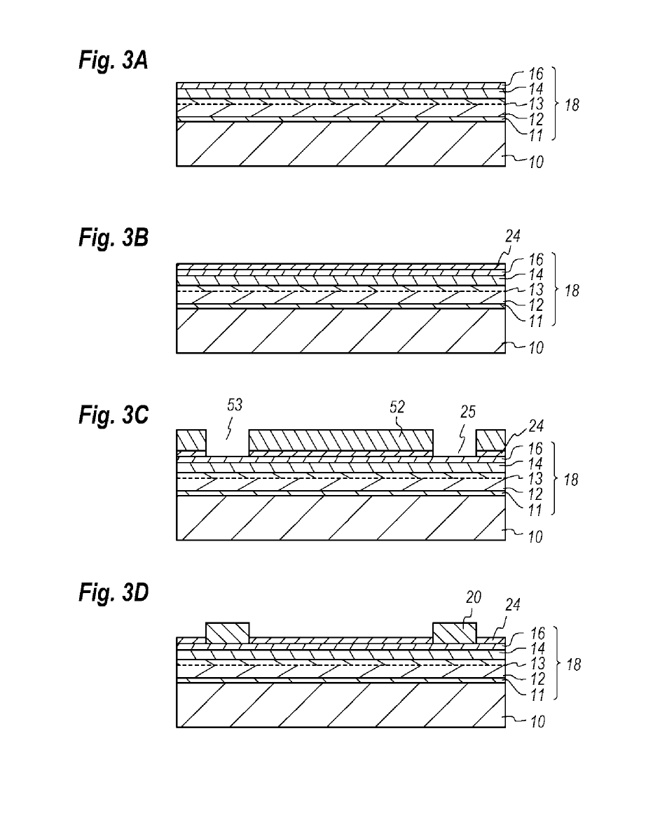

The second embodiment according to the present invention investigates the contact resistance of the ohmic electrode 20 against the semiconductor stack 18 by practically forming a transistor type of high electron mobility transistor (HEMT). Cross sections of the transistor at respective steps of the process are shown in FIG. 3A to FIG. 5C.

Same with the first embodiment, the process first grows semiconductor layers, 11 to 14 and 16, by the MOCVD technique to form the semiconductor stack 18 on the substrate 10, which is shown in FIG. 3A. Then, another insulating film 24 different from the former insulating film 22, is first formed on the semiconductor stack 18 by a thickness greater than 20 nm, as shown in FIG. 3B. The insulating film 24, which may be sometimes called as a substrate passivation film to protect the surface of the semiconductor stack 18, is formed by the p-CVD technique and has refractive index of 1.8, namely, has a composition substantially equal to the stoichiometric composition.

Thereafter, a patterned mask 52 made of photoresist is formed on the insulating film 24, where the patterned mask 52 has an opening 53 in a position where an ohmic electrode is to be formed. The insulating film 24 is partially dry-etched using a reaction gas containing fluorine (F) to form an opening 25. Because the dry-etching using fluorine (F) gas is hard to etch the nitride semiconductor material, only the insulating film 24 forms the opening 25. Then, sequential processes of evaporating the ohmic metal 20 and removing the patterned mask 52 concurrent with residual metals deposited on the patterned mask 52, the ohmic metal 20 isolated from each other is left on the semiconductor stack 18 so as to fill the opening 25 in the insulating film 24, as shown in FIG. 3D. In the present embodiment, the ohmic metal 20 includes a Ti film with a thickness of 20 nm, an Al film with a thickness of 100 nm, another Ti film with a thickness of 20 nm, and an Au film with a thickness of 50 nm.

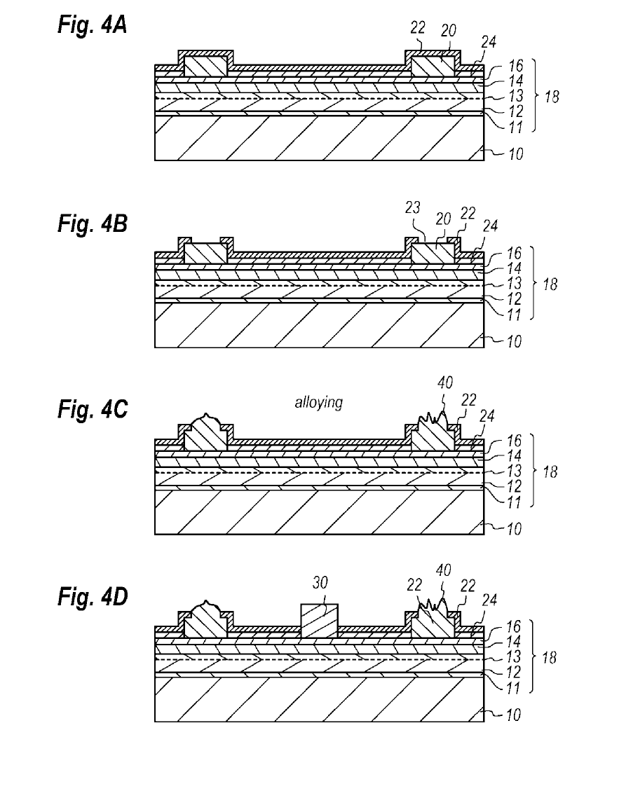

Thereafter, the insulating film 22 is formed so as to cover the insulating film 24 and the ohmic metal 20, as shown in FIG. 4A. The insulating film 22, which is formed by the p-CVD technique similar to the aforementioned embodiment, has a thickness of 40 nm and the refractive index of 1.8, namely, the composition thereof closer to the stoichiometric composition. Then, the insulating film 22 in a portion overlapping with the top of the ohmic metal 20 is etched by the dry-etching using a reaction gas containing fluorine (F), FIG. 4B, and subsequently, carries out alloying at a temperature of 850° C. for 30 second. The alloying inevitably causes bumps in the top of the ohmic electrode 20 exposed from the insulating film 22 but substantially no lumps in the root portion, or the edge of the ohmic electrode 20, as shown in FIG. 4C.

Thereafter, the gate electrode 30 is formed between the ohmic electrodes 20 by a sequential process of, patterning a photoresist to form an opening in a position where the gate electrode 30 is to be formed, etching the insulating films, 22 and 24, exposed within the opening of the photoresist, depositing the gate metal including Ni with a thickness of 80 nm and Au with a thickness of 300 nm, and removing the photoresist concurrently with residual metals deposited on the photoresist. Thus, the gate electrode is formed between the ohmic electrodes 20 and in contact with the semiconductor stack 18.

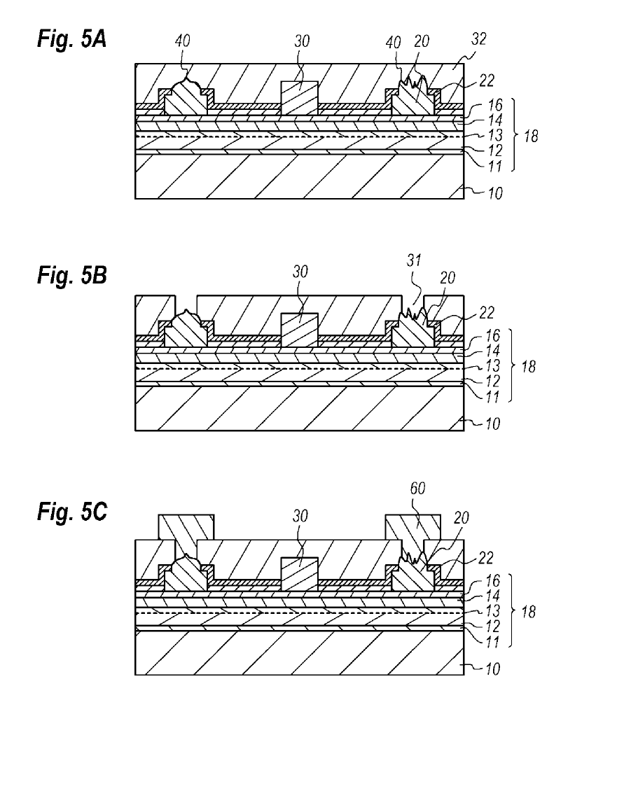

Thereafter, as shown in FIG. 5A, still another insulating film 32 made of SiN covers the insulating film 22, the ohmic electrodes 20, and the gate electrode 30, where the insulating film 32 is formed by the p-CVD technique. In an alternative, the insulating film 32 may be made of silicon di-oxide (SiO₂), silicon oxy-nitride (SiON), and so on. Forming an opening 31 in the insulating film 32, an interconnection 60 is formed so as to fill the opening 31 and to be in contact with the ohmic electrode 20. The interconnection 60 may be made of plated gold (Au), as shown in FIG. 5C.

The contact resistance of the ohmic electrode 20 against the semiconductor stack 18 is compared with those formed by conventional techniques. The contact resistance ρc of 55 points within a 4-inch wafer was measured by transfer length method (TLM). The ohmic electrode 20 of the present invention indicated the contact resistance ρc of 3.4×10⁻⁶ Ωcm². On the other hand, ohmic electrodes formed by a conventional technique where the ohmic metal is alloyed without any insulating film covering the ohmic metal indicated the contact resistance of 6.1×10⁻⁶ Ωcm², which is almost twice of the contact resistance obtained in the present embodiment. Also, still another ohmic electrode, which was alloyed fully covered with the insulating film, indicated the contact resistance of 2.7×10⁻⁵ Ωcm², which is almost one digit greater than that obtained in the present embodiment.

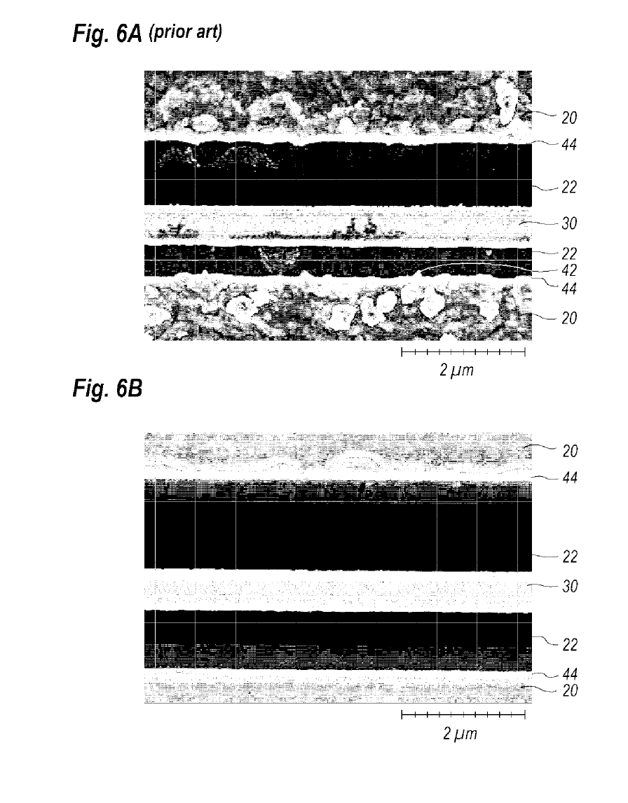

FIG. 6A and FIG. 6B compare SEM photographs of the ohmic electrode formed by the conventional process that alloys the ohmic metal covered with no insulating film (FIG. 6A) and by the embodiment where the ohmic metal only in the side is covered with the insulating film. As shown in FIG. 6A, the conventional process leaves many lumps and bumps 42 in the edge 44 of the ohmic electrode 20; while, the embodiment of the present invention forms an almost linear edge 44 in the ohmic electrode 20 and no lumps and bumps on the ohmic electrode 20, as shown in FIG. 6B.

The second embodiment of the present invention first forms the insulating film 24 before depositing the ohmic metal 20, which may effectively protect the surface of the semiconductor stack 18. The semiconductor stack 18 in the surface thereof is prevented from oxidization, contamination, and so on. When the insulating film 24 is made of SiN, the insulating film 24 preferably has the refractive index smaller than 1.9 to suppress or prevent of forming aluminum silicide (AlSi) between aluminum in the ohmic metal 20 and silicon in the insulating film 24 during the heat-treatment.

The embodiment thus described concentrates on an arrangement that the ohmic electrode 20 is formed on the cap layer 16 in the semiconductor stack 18. However, the ohmic electrode 20 may be formed on the barrier layer 14 by partially removing the cap layer 16 and being buried within the cap layer 16. Also, the embodiments concentrate on the transistor type of HEMT. However, the process of forming the ohmic electrode of the present invention may be applicable to other types of semiconductor devices.

Although the present invention has been fully described in conjunction with the preferred embodiments thereof with reference to the accompanying drawings, it is to be understood that various changes and modifications may be apparent to those skilled in the art. Such changes and modifications are to be understood as included within the scope of the present invention as defined by the appended claims, unless they depart therefrom.

What is claimed is:

1. A process of forming an ohmic electrode on to a nitride semiconductor material, comprising steps of:
depositing an ohmic metal on the nitride semiconductor material, the ohmic metal being an isolated pattern having a top and a side;
forming an insulating film such that the insulating film covers the side of the ohmic metal but exposes the top of the ohmic metal; and
alloying the ohmic metal.

2. The process according to claim 1,
wherein the ohmic metal includes a titanium (Ti) film in contact with the nitride semiconductor layer and an aluminum (Al) film, and
wherein the step of alloying the ohmic metal is carried out at a temperature of 700 to 900° C.

3. The process according to claim 1,
wherein the ohmic metal includes a tantalum (Ta) film in contact with the nitride semiconductor layer and an aluminum (Al) film, and
wherein the step of alloying the ohmic metal is carried out at a temperature of 500 to 700° C.

4. The process according to claim 1,
wherein the step of alloying the ohmic metal is carried out for 30 to 60 seconds.

5. The process according to claim 1,
wherein the ohmic metal includes aluminum (Al), and
wherein the step of forming the insulating film is carried out such that the insulating film is made of silicon nitride with refractive index thereof smaller than 1.9.

6. The process according to claim 5,
wherein the step of forming the insulating film is carried out such that the insulating film has a thickness greater than 10 nm.

7. The process according to claim 6,
wherein the steps of forming the insulating film is carried out such that the insulating film has the thickness of 40 nm.

8. The process according to claim 1,
further including steps of, before the step of depositing the ohmic metal,
forming another insulating film on the nitride semiconductor material, and
forming an opening in the another insulating film,
wherein the step of depositing the ohmic metal includes a step of depositing the ohmic metal into the opening in the another insulating film, and
wherein the step of forming the insulating film includes a step of forming the insulating film on the another insulating film.

9. The process according to claim 8,
wherein the step of forming the another insulating film is carried out such that the another insulating film has refractive index smaller than 1.9.

10. The process according to claim 8,
wherein the step of forming the another insulating film is carried out such that the another insulating film has a thickness greater than 20 nm.

11. The process according to claim 1,
wherein the semiconductor material includes a plurality of semiconductor layers each made of nitride semiconductor materials.
